(19) United States
(12) Patent Application Publication
(10) Pub. No.: US 2002/0171408 A1
(43) Pub. Date: Nov. 21, 2002

(54) Method and apparatus for display generation in digital oscilloscope

(76) Inventor: Victor L. Hansen, Portland, OR (US)

Correspondence Address: THOMAS F. LENIHAN, Tektronix, Inc., P.O. Box 500, D/S 50-Law, Beaverton, OR, 97077, US

(21) Appl. No.: 09/828,647

(22) Filed: Apr. 5, 2001

(51) Int. Cl. G01R 13/14

(52) U.S. Cl. 324/76.15

(57) ABSTRACT

A digital oscilloscope produces a waveform display of a test signal from a unit-under-test, and includes the following circuitry. A sampler generates a plurality of samples representing the test signal. An interpolation filter produces a plurality of interpolated samples intermediate the samples from the sampler, and also passes the samples representing samples from the sampler substantially unchanged. A display generator is coupled to the interpolation filter and generates an array of pixels representing the waveform display corresponding to the samples from the interpolation filter. The pixels in the array corresponding to samples from the sampler have a higher intensity than interpolated samples.

### FIELD OF THE INVENTION

The present invention relates to digital storage oscilloscopes, and in particular to a method and apparatus for generating an image on the display device of the oscilloscope representing the waveform of a signal from a unit-under-test.

### BACKGROUND OF THE INVENTION

Digital storage oscilloscopes (DSOs) are well known. They operate by sampling a signal from a unit-under-test (UUT), then from those samples generating an image on a display device representing the waveform of that signal. The values of the received samples represent the instantaneous measured characteristic, e.g. the voltage, of the signal. The received samples are processed by circuitry in the DSO to generate an array of pixels representing an image of the waveform of the signal, and the pixels are displayed on the display device, all in a known manner.

Under most conditions, there are sufficient samples taken of the signal from the UUT to generate an array of pixels accurately representing the waveform of that signal. However, there are conditions under which the number of samples taken of the signal from the UUT is insufficient to generate an array of pixels accurately representing the waveform of that signal. Under these conditions, pixels must be approximated for the waveform image locations between those locations represented by the received samples. There are many methods of forming an image of the waveform from the samples of the UUT signal under these conditions.

FIG. 1 is a set of waveform diagrams illustrating prior art methods of generating a waveform display representing a signal from a unit-under-test from samples of that signal. FIG. 1a is a waveform diagram 102 representing a characteristic (e.g. voltage) of a signal from a UUT. This diagram includes a step function at time ts. Waveform diagrams in FIG. 1b through h represent the same time portion of the waveform 102, around time ts, and include a representation of the waveform 102 as either a solid (b and d-h) or a dashed (c) line.

A first method for generating intermediate pixels is to interpolate them from the received samples. This method is illustrated on the left side of FIG. 1. The topmost waveform diagram on the left side, FIG. 1b, illustrates samples 104 taken of the signal 102. Sample times are illustrated by thin vertical lines, and the values of the samples 104 are illustrated by solid circles along the waveform 102. This method entails applying an interpolation filter to the received samples 104 to generate the intermediate pixels between the pixels representing the received samples.

Several interpolation filters are known. One known filter is the linear interpolation filter (not shown in FIG. 1). Using this filter, intermediate samples are generated such that a straight line is produced between the originally received samples. Another known filter is a

$$\frac{sin x}{x}$$

filter. In this filter, intermediate samples are generated along curves more closely approximating the signal from the UUT than the straight lines produced by the linear interpolation filter. The values generated by such interpolation filtering for the original samples 104 are not necessarily the same as those of the samples themselves. That is, the

$$\frac{sin x}{x}$$

interpolation filter may change the values of the interpolated samples representing the original samples 104.

Interpolating intermediate pixels by applying an inter-polation filter to the originally received samples can produce a waveform image which does not accurately represent the actual waveform of the signal from the UUT. Under some conditions, the differences between the waveform displayed by interpolated samples and the actual waveform are so minor as to be imperceptible to the user. However, under other conditions, the differences are vast and would be highly visible. One such condition is the presence of a step function in the observed characteristic of the signal from the UUT, as illustrated in FIG. 1. For example, when

$$\frac{sin x}{x}$$

filter is used to interpolate a waveform in the neighborhood of a step function, the interpolated waveform exhibits ringing on the lower and upper levels adjacent to, and on either side of, the step. This is illustrated in FIG. 1c, illustrating the actual waveform 102 of the signal from the UUT as a dashed line, the samples 104 (c) of the signal 102, and the resulting interpolated waveform image 106. As described above, the displayed interpolated waveform image 106 has values at the time locations of the samples 104 (c) which are not necessarily the same as the values of the corresponding original samples 104 (c).

The displayed waveform 106 could be incorrectly interpreted by a user as indicating an actual ringing in the signal from the UUT, while instead it is merely a manifestation of the interpolation process used to generate the displayed waveform 106. In any event, the waveform 106 thus generated is not a completely accurate representation of the waveform of the signal 102 from the UUT in the time neighborhood of the step.

Furthermore, in current DSOs, intermediate samples are interpolated by a microprocessor in the signal path of the DSO between the probe and the display device. The originally received samples 104, representing the signal 102 from the UUT, are stored in a sample memory. The microprocessor accesses the originally received samples 104 in the sample memory and generates interpolated samples from the original samples 104. An array of pixels representing the waveform 106 of the signal 102 is generated from the interpolated samples. The array of pixels representing the image of that waveform 106 is then stored in a display memory. (The sample memory and display memory may be separate portions of a single memory device). The pixel array in the display memory is then read by the display device to generate the waveform 106 image on the display device. However, such processing by a microprocessor is slow, and capable of producing no more than on the order of several hundred new images per second, regardless of the speed of the signal.

A second method for generating intermediate pixels takes advantage of the asynchronicity between the signal from the UUT and the timing of the samples taken of that signal and is illustrated on the right side of FIG. 1. This method is sometimes called “equivalent time sampling”. When samples are taken of the signal from the UUT, the sampling clock is not synchronous with that signal. The signal from the UUT is monitored by the trigger circuit, and when the trigger event occurs a record of samples is generated representing the signal. However, as described above, the sampling clock is asynchronous with the trigger, so the sampling times will vary, relative to the signal from the UUT, from scan to scan. By accumulating samples from a plurality of records, samples from sufficient time locations may be accumulated to accurately produce the pixel array representing that waveform without requiring interpolation.

FIG. 1d is identical to FIG. 1b. In FIG. 1d, a first record of samples 104 (d) is taken of the signal 102. More specifically in FIG. 1d, a sample 108 is taken at the bottom of the step and a sample 110 is taken after the step. The time positions of samples 108 and 110, relative to the waveform 102, are indicated by respective thin vertical lines through FIG. 1d, e, f, g and h. In FIG. 1e, a second record of samples 104 (e) is taken of the signal 102. These samples are not time aligned with the samples 104 (d) taken during the record illustrated in FIG. 1d. More specifically in the neighborhood of time ts, sample 112 is at a slightly later time, relative to the waveform 102, than sample 108 was, and is slightly up the step. Referring to FIG. 1f, another record of samples 104 (f) is taken of the signal 102. In FIG. 1f, sample 114 is later, relative to waveform 102, than sample 112 was, and is further up the step. Referring to FIG. 1g, yet another record of samples 104 (g) is taken of the signal 102. In FIG. 1g, sample 116 is later, relative to waveform 102 than sample 114 was, and is nearly at the top of the step.

As these records are taken, all of the samples are stored, along with their relative time positions, in a memory, which may be the sample memory. One skilled in the art will understand that as more records of samples are taken, the time density of the samples increases. When samples representing enough records have been stored so that the sample time density is high enough, the image of the waveform 102 of the signal from the UUT may be generated from the stored samples without requiring interpolation. This is illustrated in FIG. 1h in which the samples taken in all the records illustrated in FIG. 1a-g are combined into a single record. The display generator then analyzes all these samples and generates a waveform from them which accurately reflects the signal from the UUT.

One skilled in the art will understand from the above description that producing a single waveform display using equivalent time sampling takes an amount of time necessary to accumulate sufficient time density of the received samples. Thus, waveform displays are produced at a relatively low rate. However, a waveform image generated in the equivalent time sampling mode, described above, will generate a highly accurate waveform representing the signal from the UUT, provided that both the signal and the triggering is stable over the time period necessary to accumulate sufficient samples. If the signal is not stable over that time period, then the samples taken over the successive records will have different values. This can appear to the user as high frequency noise in the signal. If the triggering is not stable over that time period, then the sample times will vary over the successive records. This can appear to the user as time jitter in the signal. Under either of these conditions, the waveform 106 generated from these records is not a completely accurate representation of the signal 102 from the UUT.

Recent DSOs have included a display device for displaying the array of pixels in which each pixel can display various shades of gray, termed gray scale mode, or different colors. Using the gray scale mode has allowed DSOs to display waveforms having a similar appearance to those analog oscilloscopes would display. In an analog oscilloscope, the more often the waveform appears at a particular point on the display screen, the brighter that point is, while a point on the display screen which is only once or very seldom included in the waveform, is displayed dimmer. In a DSO, a database of each pixel is maintained, and each time the waveform passes through that pixel, the brightness of that pixel is increased, while the brightness is decayed slowly when the waveform does not pass through the pixel. This feature is termed digital phosphor decay.

Alternatively, many sample records may be accumulated in the sample memory between each waveform display refresh cycle. As the waveform display is being generated from the accumulated sample records in the sample memory, the number of times the waveform passes through a pixel is accumulated, and the brightness of each pixel is set according to the accumulated value, and the resulting image is displayed on the display device. Oscilloscopes with one of these features are termed digital phosphor oscilloscopes (DPOs).

### BRIEF SUMMARY OF THE INVENTION

The inventor has realized that the gray scale capability of a DPO can be combined with the interpolating and equivalent time sampling capability of a DSO to more provide a higher accuracy display of waveforms under those conditions where the inaccuracies described above would result.

In accordance with principles of the present invention, a digital oscilloscope produces a waveform display of a signal from a unit-under-test (UUT), and includes the following circuitry. A sampler generates a plurality of samples representing the signal from the UUT. An interpolation filter produces a plurality of samples, including interpolated samples intermediate the samples from the sampler. During the process of interpolation, the interpolated samples representing samples from the sampler are preserved substantially unchanged by the interpolation filter. A display generator is coupled to the interpolation filter and generates an array of pixels representing the waveform display corresponding to the samples from the interpolation filter. The pixels in the array corresponding to samples from the sampler are displayed with a higher intensity than interpolated samples.

### BRIEF DESCRIPTION OF THE DRAWING

In the drawing:

FIG. 1 is a set of waveform diagrams illustrating prior art methods of generating a waveform display representing a signal from a unit-under-test from samples of that signal;

FIG. 2 is a block diagram of a portion of a digital oscilloscope according to principles of the present invention;

FIG. 3 is a diagram illustrating coefficients for an interpolation filter which may be used in an oscilloscope according to principles of the present invention; and

FIG. 4 is a set of waveform diagrams illustrating the operation of an oscilloscope according to the present invention.

### DETAILED DESCRIPTION OF THE INVENTION

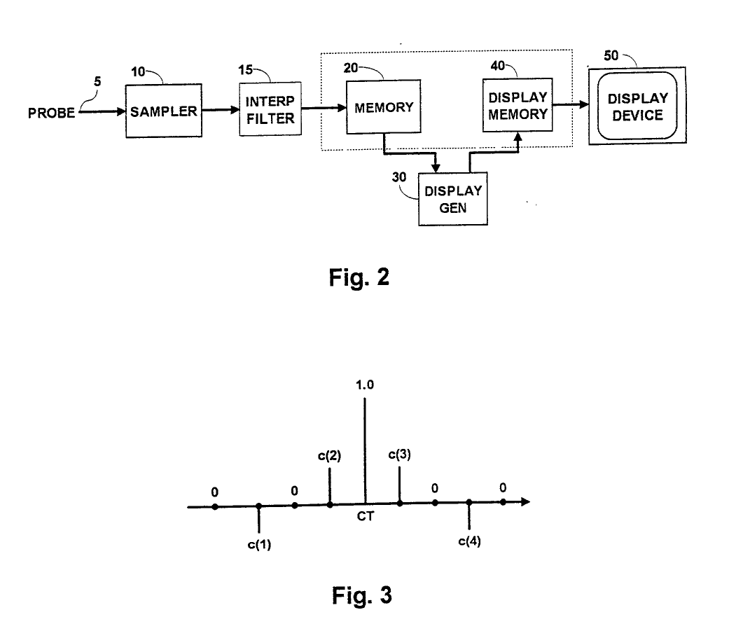

FIG. 2 is a block diagram of a portion of a digital oscilloscope according to principles of the present invention. In FIG. 2, a probe 5 is coupleable to a circuit node (not shown) in a unit-under-test (UUT). The probe 5 is coupled to an input terminal of a sampler 10. An output terminal of the sampler 10 is coupled to an input terminal of a hardware interpolation filter 15. An output terminal of the interpolation filter 15 is coupled to an input terminal of a sample memory 20. An output terminal of the sample memory is coupled to an input terminal of a display generator 30. An output terminal of the display generator 30 is coupled to an input terminal of a display memory 40. As described above, the sample memory 20 and display memory 40 may be implemented as different sections of the same memory device, represented in FIG. 2 by a dashed line around the sample memory 20 and display memory 40. An output terminal of the display memory 40 is coupled to an input terminal of a display device 50. The display device 50 generates an image of a waveform of the signal at the circuit node to which the probe 5 is coupled in a manner to be described in more detail below.

In operation, the probe 5 is coupled to a circuit node in the UUT (not shown). The signal at the circuit node of the UUT is sampled by the sampler 10. The interpolation filter 15 receives a record of samples from the sampler 10 and generates a sequence of samples including samples representing the samples from the sampler 10 preserved substantially unchanged, and interpolated samples for time locations between the samples from the sampler 10, all in a manner to be described in more detail below. The number of samples in the record so generated depends on the sampling frequency and the speed of the signal from the UUT.

The interpolation filter 15 is a hardware filter, instead of a microprocessor programmed with the filtering algorithm, in order to produce records of interpolated samples at a faster rate than microprocessor driven filters can. Further-more more, the interpolation filter 15 is one of a class of interpolation filters which preserves the values of the input samples, from the sampler 10, substantially unchanged. Interpolation filters are known which can provide this characteristic, and are generally termed “N-band” filters. The simplest form of an N-band filter is for N =2, and is commonly termed a half-band filter. In a half-band filter, a center tap coefficient has the value of 1.0. The coefficients at alternating taps on either side of the center tap have the value zero, while the coefficients of the remaining taps have non-zero values.

FIG. 3 illustrates coefficient values for a half-band interpolation filter 15 which may be used in an oscilloscope according to principles of the present invention. In FIG. 3, a center tap (CT) is shown having a coefficient value of 1.

Coefficients for alternating taps on either side of the center tap CT have the value 0, while the coefficients (c(1) to c(4)) of the remaining taps have non-zero values.

More specifically, N-band filters, such as interpolation filter 15, may be composed of a plurality of sub-filters. The coefficient of the center tap of one of the sub-filters has a value of 1, while the coefficients of the center taps of the other sub-filters have the value 0. In a similar manner to the half-band filter described above, this substantially preserves the value of the input sample from the sampler 10.

One skilled in the art will understand that it is not required that the interpolation sub-filters be precisely N-band filters, but instead will understand that it is sufficient if the overall characteristic is sufficiently close to the N-band characteristic to provide the property that the input samples, from the sampler 10 are preserved substantially unchanged.

The sequence of samples from the interpolator 15, including samples representing the original samples from the sampler 10 and interpolated samples between them, are stored in the sample memory 20. The display generator 30 retrieves all of the samples (both original and interpolated) from the sample memory 20, and generates a pixel array in the display memory 40 representing an image of the waveform of the characteristic of the signal from the UUT. The display device 50 then displays the image represented by the pixel array interpolated from the successive records of samples.

In one embodiment using the digital phosphor decay technique, described above, each pixel array is displayed on the display device 50 as soon as it is generated. As described above, in a digital phosphor decay DSO, when the displayed waveform passes through a pixel, the intensity of that pixel is increased, and when the displayed waveform does not pass through a pixel, its intensity decays. Because the interpolated samples representing the original samples retain the value of the original sample, pixels at locations corresponding to original samples correspond to the actual waveform of the signal from the UUT. Pixels representing interpolated samples, at times between those of the original samples, have values generated by the interpolation filter 15 which would in general be different from the value of the actual signal from the UUT.

As a large number of sample records are received and displayed, the locations in the pixel array in the display memory 40 representing the actual waveform of the signal from the UUT will be represented by samples which recur regularly, while pixels at other locations will tend to be represented by samples which recur more randomly and less often. The pixel locations representing the actual signal from the UUT, thus, will tend to have a higher intensity than those pixels representing interpolated values not corresponding to the actual signal from the UUT. Consequently, as a large number of sample records are accumulated, the image displayed on the display device 50 will show the waveform of the signal from the UUT at a higher intensity.

In an alternative, preferred, embodiment, the sampler 10, interpolation filter 15, sample memory 20 and display generator 30 are configured to have a relatively high update rate between triggers, while the display device 50 is refreshed at a much lower rate, e.g. 1/30 sec. In this embodiment, many pixel arrays, representing the respective sample records, are accumulated in the display memory 40 between display device 50 refresh cycles. As the pixel arrays are being accumulated, the intensity of each pixel in the array is incremented each time an accumulated waveform passes through that pixel. I.e. the more times a waveform passes through a pixel, the higher the intensity of that pixel. The visual effect of accumulating pixel arrays representing respective sample records is that the waveform images representing each respective sample record are visually overlaid atop each other.

When a display device 50 refresh time occurs, the accumulated pixel array in the display memory 40 is displayed on the display device 50, and the display memory 40 is cleared to receive the next set of accumulated pixel arrays. As described above, locations in the pixel array in the display memory 40 representing the actual waveform of the signal from the UUT will recur regularly, while pixels at other locations will tend to recur more randomly and less often. The pixel locations representing the actual signal from the UUT, thus, will have a higher intensity than those pixels representing interpolated values not corresponding to the actual signal from the UUT. Consequently, as pixel arrays representing a large number of sample records are accumulated, the image displayed on the display device 50 will show the waveform of the signal from the UUT at a higher intensity.

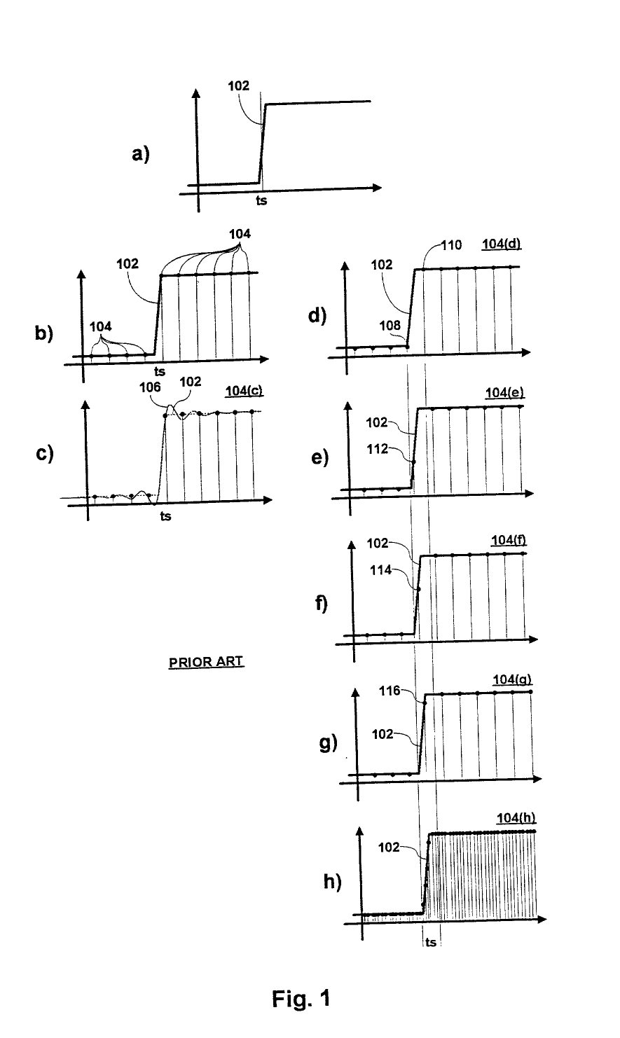

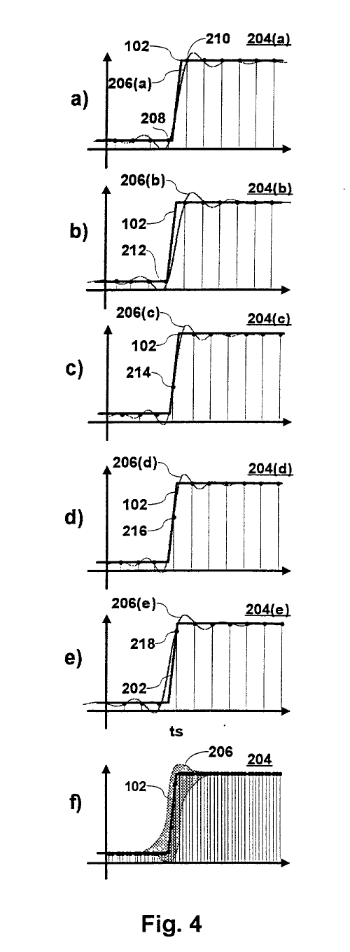

FIG. 4a to f illustrate waveforms interpolated from respective records of samples and represented by corresponding pixel arrays. The waveforms illustrated in FIG. 4 are similar to those illustrated in FIG. 1. In FIG. 4, the timing of the original samples from the sampler 10 is represented by the thin vertical lines, and the values of the original samples are represented by the circles along the waveform 102 representing the signal from the UUT. FIG. 4a illustrates a waveform interpolated from a first record of samples 204 (a). The waveform 206 (a) is the image represented by the pixel array generated by the interpolation filter 15 in response to the record of samples 204 (a). As in FIG. 1b and c, the interpolation filter 15 introduces ringing adjacent to, and on either side of, the transition in the interpolated waveform image of the signal 102 from the UUT. Because of the characteristic, described above, of the interpolation filter 15, the values of the original samples from the sampler 10 are preserved substantially unchanged. The interpolated waveform 206 (a), therefore, passes through the original samples 204 (a) from the sampler 10.

FIG. 4b illustrates a waveform interpolated from a second record of samples 204(b). The original samples 204 (b) in FIG. 4b are at different times relative to those in FIG. 4a. The interpolated waveform 206 (b) generated from the original samples 204 (b) also exhibits a ringing adjacent to, and on either side of, the step in the signal 102 from the UUT. This interpolated signal 206 (b) also passes through the locations of the original samples 204 (b). FIG. 4c to e, similarly show interpolated waveforms 206 (c) to 206 (e), processed from respective records of original samples 204 (c) to 204 (e). Each exhibits ringing on either side of the step in the signal 102 from the UUT, and in each, the interpolated waveform 206 (c) to 206 (e) pass through the respective original samples from that record 204 (c) to 204 (e). One skilled in the art will observe that the interpolated waveforms at the times corresponding to the original samples lie atop the signal 102 from the UUT, while the remaining, interpolated, samples make respectively different interpolated waveform displays.

In the first embodiment described above, each waveform 206(a)-206(e)) is displayed immediately as it is created.

The digital phosphor decay characteristic results in the pixels at locations corresponding to the actual signal 102, which recur regularly, being displayed at a higher intensity, for the reasons described above. In the second embodiment, described above, the respective pixel arrays are accumulated in the display memory 40. The intensity of the pixels are incremented as the pixel arrays are accumulated. When the display device 50 is refreshed, the pixels at locations corresponding to the actual signal 102 have higher intensity, for the reasons described above.

FIG. 4f illustrates an image displayed on the display device 50 generated according to either of the first and second embodiments described above. In FIG. 4f, the circles, representing the original samples are displayed at higher intensity and present an accurate waveform display of the signal 102 from the UUT. There is an envelope 206 surrounding this waveform display, within which pixels representing the interpolated samples, i.e. those not representing the actual waveform, are displayed. Because they recur less often than pixels representing the actual signal 102, for the reasons given above, they are displayed at a lower intensity. In addition, the further from the waveform representing the actual signal 102, the dimmer the pixels. This envelope 206 appears only as a dim background.

Because of the hardware interpolation filter 15, records of samples may be processed and displayed rapidly, and the display device 50 can display a waveform image which can accurately reflect changes in the signal 102 from the UUT. The apparent high frequency noise caused by signal changes and apparent jitter caused by trigger event changes, which can occur in equivalent time mode, are avoided because of the higher display refresh rate made possible by the hardware filter. The use of the digital phosphor mode, in conjunction with the N-band filter, with its characteristic of preserving input samples substantially unchanged, allows the input samples, representing the actual signal from the UUT, to be displayed with a higher intensity.

What is claimed is:

1. In a digital oscilloscope, circuitry for producing a waveform display of a test signal, comprising:
a sampler, for generating a plurality of samples representing the test signal;
an interpolation filter, coupled to the sampler, for producing a sequence of interpolated samples including samples representing the samples from the sampler substantially unchanged, and interpolated samples intermediate the samples from the sampler;
a display generator, coupled to the interpolation filter, for generating an array of pixels representing a waveform image corresponding to the interpolated samples, in which pixels representing the test signal have a higher intensity than remaining pixels.

2. The digital oscilloscope circuitry of claim 1 wherein the interpolation filter comprises a hardware filter.

3. The digital oscilloscope circuitry of claim 2 wherein the interpolation filter exhibits a substantially N-band filter characteristic.

4. The digital oscilloscope circuitry of claim 3 wherein the interpolation filter exhibits a substantially half-band filter characteristic.

5. The digital oscilloscope circuitry of claim 1 wherein the interpolation filter comprises an N-band filter.

6. The digital oscilloscope circuitry of claim 5 wherein the interpolation filter comprises a half-band filter.

7. The digital oscilloscope circuitry of claim 1 wherein the display generator operates in a digital phosphor mode.

8. The digital oscilloscope circuitry of claim 7 wherein the display generator operates in a digital phosphor decay mode.

9. The digital oscilloscope circuitry of claim 7 wherein:
the sampler generates successive records of samples representing the test signal;
the interpolator produces a corresponding sequence of interpolated samples for each record of samples from the sampler; and
the display generator comprises a display memory for accumulating arrays of pixels representing respective sequences of interpolated samples such that pixels representing the waveform image of each successive record are increased in intensity, thereby displaying pixels representing samples from the sampler at higher intensity.

10. The digital oscilloscope of claim 9 wherein the display generator generates a waveform image on a display device representing the accumulated pixel arrays in the display memory then clears the display memory.
